(19) United States
(12) Patent Application Publication
(10) Pub. No.: US 2013/0220421 A1
(43) Pub. Date: Aug. 29, 2013

(54) METHODS AND APPARATUS USING ASPHALTENES IN SOLID-STATE ORGANIC SOLAR CELLS

(71) Applicants: Michael D. Irwin, El Paso, TX (US); Russell R. Chianelli, El Paso, TX (US); Robert D. Maher, III, Plano, TX (US)

(72) Inventors: Michael D. Irwin, El Paso, TX (US); Russell R. Chianelli, El Paso, TX (US); Robert D. Maher, III, Plano, TX (US)

(73) Assignee: Hunt Energy IQ, LP, Dallas, TX (US)

(21) Appl. No.: 13/588,737

(22) Filed: Aug. 17, 2012

Related U.S. Application Data
(60) Provisional application No. 61/525,564, filed on Aug. 19, 2011.

(51) Int. Cl. H01L 51/00

(52) U.S. Cl. CPC H01L 51/0067
USPC 136/263; 208/44; 252/500; 438/93

(57) ABSTRACT

Apparatus and methods are described using asphaltene and its derivatives as semi-conducting materials in photovoltaic cells. Asphaltene is used in an organic PV device as either or both of a p-type material and/or n-type material. The asphaltene-based material can be treated such as by de-metalization, metal addition, extraction, fractionation, and optimization of the asphaltene material. Treatment can be selected to create an asphaltene-based material having pre-selected characteristics, such as absorption value, reflectance, index of refraction, band gap, etc. The asphaltene-based materials can be blended or otherwise combined with inorganic or non-asphaltene organic materials. Further, asphaltene material can be used as an interfacial layer in the PV device.

### CROSS REFERENCE TO RELATED APPLICATIONS

This application claims priority to U.S. Provisional Application Ser. No. 61/525,564 to Irwin, filed Aug. 19, 2011.

### BACKGROUND

1. Technical Field

This invention relates, generally, to apparatus and methods of use of materials in organic photovoltaic cells in creating electrical energy from solar radiation. More specifically, this invention relates to apparatus and methods of use of asphaltene and its derivatives as organic semi-conducting materials in solar photovoltaic cells and photovoltaic cells using such materials.

2. State of the Art

Use of photovoltaics (PVs) to generate electrical power from solar energy or radiation is known in the art. Benefits of PV technology include use of a vast, infinite power source, low or zero emissions, power production independent of the power grid, durable physical structures (no moving parts), stable and reliable systems, modular construction, relatively quick installation, safe manufacture and use, and good public opinion and acceptance of use. These benefits outweigh the disadvantages and difficulties in solar energy, including a diffuse power source, sizable energy investment, lacking infrastructure, and limited energy storage technology.

Prior art patent disclosures and public information discuss Solid-State Organic Solar Cells. These devices use organic semi-conducting materials in combination with structured or planar inorganic materials. The photo-conversion processes valid for conventional PV cells is also applicable to all four currently existing types of organic PV (OPV) cells: dye-sensitized solar cells (DSSCs); planar organic semiconductor cells; hybrid solar cells; and high-surface-area or bulk-heterojunction (BHJ) cells. The OPV cells may be based on an organic component of fullerenes, organic dyes, semiconducting polymers, semiconducting small molecules, or some combination of these species.

Bulk-Heterojunction devices have been intensely studied over the past decade with a photo-active layer of a polymer-fullerene blend. The most common polymer-fullerene blend is a mixture of poly-3-hexylthiophene (P3HT) and phenyl-C61-butyric acid methyl ester (PCBM). BHJs typically consist of blends of the two components, where the domain size of each component is on the nanometer length scale. In these devices, optical photons are absorbed in the polymer component creating excitons (bound electron-hole pairs). The excitons then diffuse to the polymer-fullerene interface where charge separation occurs. Current is generated when the resulting free electrons and holes are transported through the donor polymer and acceptor fullerene, respectively, to the electrodes.

Additionally, in hybrid PV devices, an organic semiconductor component is matched with an inorganic semiconductor to form a p-n junction. This can be accomplished with either a p- or n-type inorganic or p- or n-type organic material appropriate to the p-n junction. A common example would be P3HT (p-type organic polymer) with CdSe (n-type inorganic solid). The inorganic material can be in the form of a nanoscopic solid, or nanopatterned or planar thin film. PV function is the same as described above.

### SUMMARY

The invention presents apparatus, methods of use, and methods of treatment of asphaltene and its derivatives (asphaltene or asphaltene-based materials) for use as organic semi-conducting materials in solar photovoltaic cells and photovoltaic cells using such materials. In a preferred method, an asphaltene material is treated for use in a photovoltaic device. An asphaltene-based p-type material or an asphaltene-based n-type material is created from an asphaltene material and used in a photovoltaic device. The asphaltene-based material can be treated prior to use by treatment methods such as de-metalization, metal addition, extraction, fractionation, and optimization of the asphaltene material. Further, the treatment steps can be selected to create an asphaltene-based material having pre-selected characteristics, such as absorption value, reflectance, index of refraction, band gap, molecular orbital energy value, effective wavelength utility, charge carrier concentration, charge carrier mobility, charge carrier effective mass, or conductivity. The PV device can be a dye-sensitized solar cell, planar organic semiconductor cell, hybrid solar cell, or BHJ cell. An asphaltene material can be used as one or both of the p-type and n-type materials. Alternately, the asphaltene-based materials can be blended or otherwise combined with inorganic or non-asphaltene organic materials. Further, in a preferred embodiment, asphaltene material can be used as an interfacial layer in the PV device. Similarly, organic PV devices are presented using asphaltene and asphaltene-based materials which can be manipulated according to the processes described above.

### BRIEF DESCRIPTION OF THE DRAWINGS

FIG. 1 is a schematic view of a typical photovoltaic cell including an active layer according to an embodiment of the invention;

FIG. 2 is a chart showing the effects of heat treatment of an asphaltene material as used in embodiments of the invention;

FIG. 3 is a schematic view of a typical asphaltene chemical structure;

FIG. 4A is a schematic, exploded and cross-sectional view of an asphaltene solubilized by Micelle structure;

FIG. 4B-C are schematic views of an exemplary asphaltene material;

FIG. 5 is a schematic diagram demonstrating bulk-heterojunction phase separation as used in embodiments of the invention;

FIG. 6 is a sample flow-chart of steps for modification or treatment of asphaltene or an asphaltene-based material for use in PV cells according to embodiments of the invention; and

FIG. 7 is an exploded, representational view of a sample PV cell having a Transparent Conducting Electrode, an Electron Blocking Layer, a p-type thin film active layer, an n-type organic active layer, a Hole Blocking Layer and a low work-function layer according to an embodiment of the invention.

### DETAILED DESCRIPTION OF PREFERRED EMBODIMENTS

An invention disclosed herein is a material system based on low-value refinery by-products found in crude oil. These by-products are known as crude oil bottoms, very heavy molecules which are difficult to refine, called asphaltenes. The asphaltene-based material systems discussed herein can replace all or parts of the donor/acceptor photoactive complex typically used in organic and hybrid PVs.

In addition to naturally occurring asphaltenes, such as from crude oil, and asphaltene by-products from refining processes, synthetic or self-assembled asphaltene materials may be used as described herein.

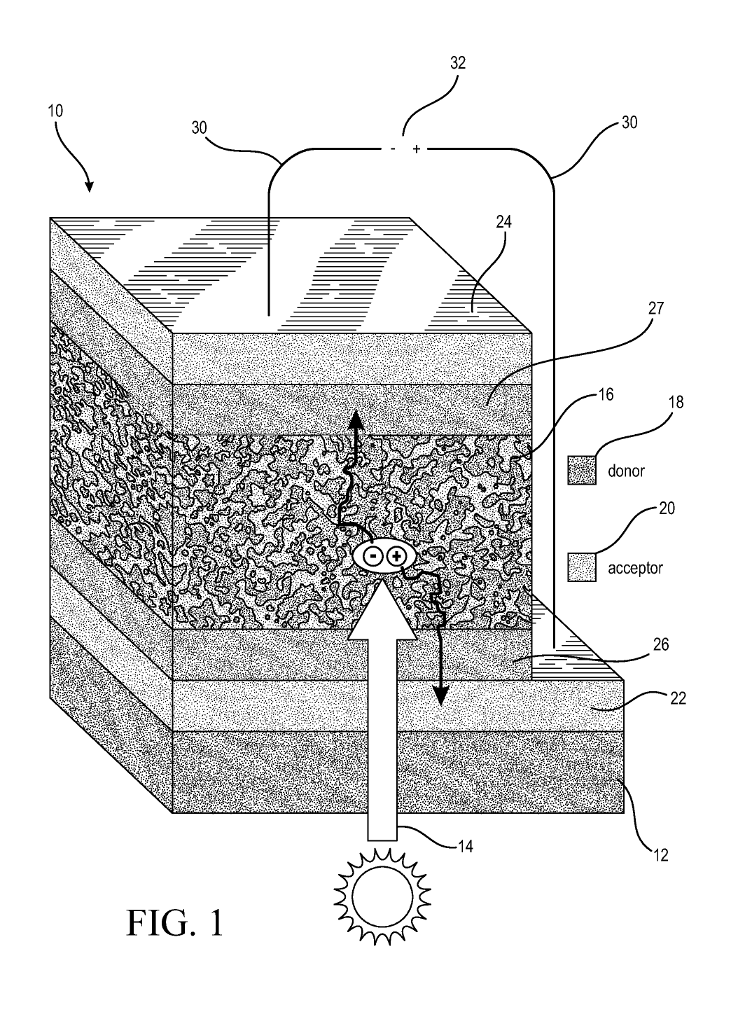

In a preferred embodiment of the invention, seen in FIG. 1, a typical PV cell 10 includes a transparent layer 12 of glass (or material similarly transparent to solar radiation) which allows solar radiation 14 to transmit through the layer. The active layer 16 is composed of donor or p-type material 18 and acceptor or n-type material 20. The photo-active layer 16 is sandwiched between two electrode layers 22 and 24, as is known in the art. In FIG. 1, the electrode layer 22 is an ITO material. The electrode layer 24 is an aluminum material. Other materials may be used as is known in the art. The cell 10 also includes an interfacial layer 26, shown as a PEDOT:PSS material. In one embodiment, the interfacial layer can be an asphaltene material which assists in charge separation. There is also an interfacial layer (IFL) 27 on the aluminum-cathode side of the device. A typical architecture is substrate-anode-IFL-photoactive layer-IFL-cathode. Other layers and materials may be utilized in the cell as is known in the art. The cell 10 is attached to leads 30 and a discharge unit 32, such as a battery, as is known in the art.

In the invention, the active layer is at least partially composed of asphaltene material. “Asphaltene material” as used herein, includes unmodified naturally occurring or synthetic asphaltene, and such asphaltenes as modified, such as by de-metalization, extraction, fractionation, and/or optimization treatment, the modification of which is described herein. Asphaltene refers to a high molecular weight fraction of crude oils that are insoluble in aliphatic solvents.

Asphaltenes are generally p-type semiconductors because they contain extended aromatic structures and metals in their porphyrin rings. Asphaltenes are photoactive semiconductor materials and can occur as p-type or n-type materials.

Various metals are typically present in naturally-occurring asphaltene. Typically, asphaltene contains amounts of vanadium and nickel. The specific structure and metal content of the asphaltene will vary depending on the source. That is, asphaltene components and percentage constitution will vary across oil products from different fields. Similarly, a synthetic asphaltene will have predetermined constituents which can be selected during synthesis. The asphaltene can be used in the active layer of a PV cell as an electron donor material.

Asphaltenes 50, such as the exemplary structure seen in FIG. 3, have complex structures. Asphaltenes typically contain primarily carbon, nitrogen, oxygen, sulfur, and hydrogen.

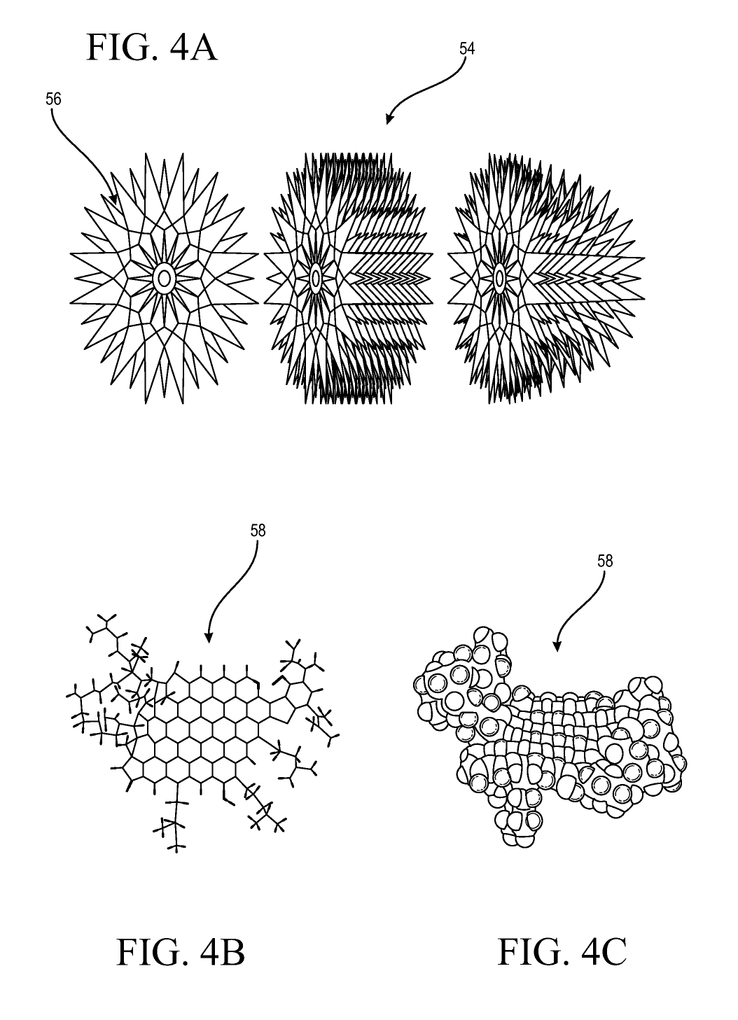

Asphaltene structures vary widely, with exemplary structures 52 seen in FIGS. 4A-C. FIG. 4A shows asphaltene as solubilized by a micelle structure 54 and having a stacked aromatic core 56 (approximately 4 nm). FIGS. 4B-C are different views of an exemplary asphaltene structure 58. The structure of a particular asphaltene is determined by short range and long-range order and can be measured by x-ray diffraction techniques.

Metals present in asphaltene can be removed from the asphaltene by de-metalization techniques. For example, asphaltene can be de-metalized such as by purification, washing with a solvent, such as toluene, or by acid-treating, such as with HF. Other methods of metal removal are known in the art and may be utilized. De-metalized asphaltene is either p- or n-type, depending on final molecular structure. The de-metalized asphaltene can be used in the active layer of a PV cell as an electron donor or acceptor material, again, depending on the final molecular structure.

Selected metals can be added to the asphaltene as desired. The added metals can, for example, “replace” removed metals. Asphaltenes with added metals can be p- or n-type materials depending on the final molecular structure. Asphaltene with substituted metals can be used in the active layer of a PV cell as an electron donor or acceptor material.

Asphaltenes are defined by their insolubility in aliphatic solvents. For example, when crude oils are treated with pentane the Pentane Asphaltenes are the part of the crude oil that is insoluble in pentane. This process is referred to as extraction. During extraction, a aliphatic solvent is utilized to extract a desired type of asphaltene from the crude oil or other asphaltene source. Thus it is possible to extract asphaltenes in the following solubility classes: Pentane Asphaltenes, Hexane Asphaltenes, Heptane Asphaltenes, Octane Asphaltenes, Nonane Asphaltenes, and alkane asphaltenes. As the alkane becomes longer, a less amount of asphaltene is recovered. For example, the percentage of asphaltene precipitated out during the extraction will be higher when using pentane and lower when using nonane.

The extracted asphaltene is referred to as an extractate. An extractate from any solubility class can be utilized in the active layer of a PV cell as the p- or n-type, or electron donor or acceptor material, respectively. An extractate can be de-metalized, or alternately, the asphaltene can be de-metalized, then extracted.

Fractionation, as used herein, refers to a process of separating into constituents or fractions containing concentrated constituents. In a preferred embodiment, the method includes the step of re-dissolving, such as in toluene/paraffin mixtures, an extracted asphaltene. Other dissolving agents are known in the art and may be used. The solvent or solvents used in the Extraction and Fractionation steps can be the same solvents or can differ. Asphaltenes from all solubility classes can be fractionated. The Fractionation process can be repeated to achieve an asphaltene material having selected or desired constituents or percentage constituencies of elements or molecules.

Asphaltenes are “tunable” by applying treatments and processes to the asphaltene to change its structure, constituent parts, etc. By treating the asphaltene, or an asphaltene derivative realized from the processes described herein, the characteristics or properties of the asphaltene material can be selected. For example, the optical absorption of the asphaltene material may be altered to maximize optical absorption. Similarly, asphaltene material can be treated to increase the bandwidth of radiation effectively absorbed by the material to increase the adsorption of solar produced photons.

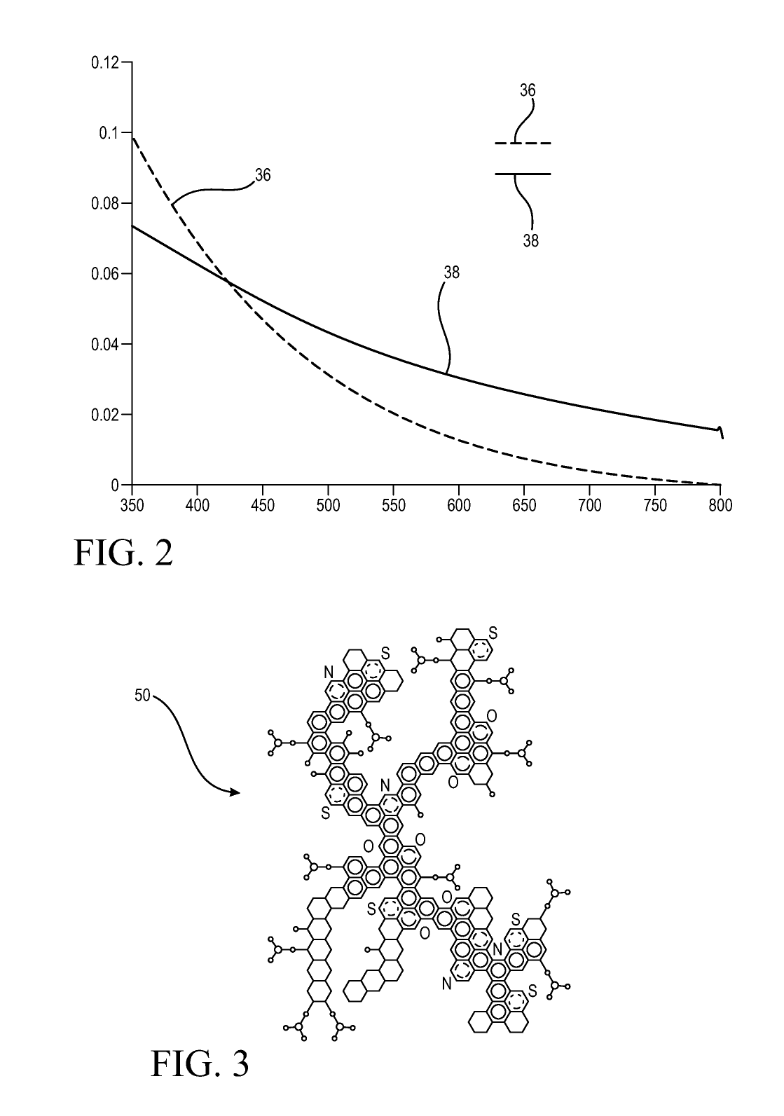

FIG. 2 presents a chart showing the effects of heat treatment of an asphaltene material. A first asphaltene compound 36, indicated as “Frac2300C10 m”, indicating the material undergoes a physical change evidenced by disappearance of the charge transfer band. Fractionate, heated to 300 degrees Centigrade for 10 minutes, showed absorption (in Arb Units) as indicated over the wavelengths (in nm) indicated. A second asphaltene compound 38, “Frac2 500C 10 m”, indicating a similar fractionate of asphaltene but heated to 500 degrees Centigrade for 10 minutes, exhibited more effective absorption over a greater range of wavelengths, especially of longer wavelengths. For example, the asphaltene material can be tuned, through heat or other treatment, to absorb infrared wavelength light.

A process for “tuning” or selecting the properties of an asphaltene is Heat Treatment or Thermal Treatment. Heating asphaltenes generates new asphaltene or asphaltene-derivative materials that have different properties from their original or “parent” asphaltenes. For example, heating an asphaltene can improve its light adsorbing properties. The asphaltene can be heated over a range of temperatures and over a range of times. For example, it is expected that an asphaltene may be heated from 200-800 degrees C. during treatment. It is expected that preferred heat treatment of an asphaltene may range, for example, from 5 to 60 minutes.

Other methods of asphaltene material treatment may be used as well to “tune” the material. For example, the asphaltene material can be optimized for its intended use by applying chemical, thermal, photochemical, and or electrochemical treatments. Such treatments can be used to select or tune the absorption values, reflectance, index of refraction, band gap, molecular orbital energy values, effective wavelength utility, charge carrier concentration, charge carrier mobility, charge carrier effective mass, conductivity/resistivity, and other characteristics and properties of the material.

As discussed above, the fractionation and extraction processes are also “tuning” methods, which can be selected as desired to achieve targeted or optimized semiconducting characteristics and properties from the asphaltene material. For example, the asphaltene can be extracted and fractionated to achieve an optimum conductivity and optimum adsorption of solar photons through changes in inter/intramolecular interactions.

Also discussed above, manipulation of the metal content of the asphaltene, such as by de-metalization, metal addition and metal substitution, can be used as “tuning” methods to procure optimal characteristics and properties in the asphaltene material. Where heavy metals may have negative effects on the effectiveness of the asphaltene, and so be desirable to remove, other metals may provide positive effects on the asphaltene properties and be added. For example, vanadium and nickel may be removed to modify the semiconducting properties of the asphaltene material. Similarly, copper, iron or other metals can be added to the asphaltene material to optimize the material properties for a particular use in this way the semiconducting properties of the asphaltene can be tuned and optimized. Such treatments can be used to select or tune the absorption values, reflectance, index of refraction, band gap, molecular orbital energy values, effective wavelength utility, charge carrier concentration, charge carrier mobility, charge carrier effective mass, conductivity/resistivity, and other characteristics and properties of the material.

Discussed above are methods of creating asphaltene materials acceptable for use in PV cells. Methods for producing both p-type and n-type materials are provided. The methods applicable for creating p-type or electron donor materials include extraction, fractionation, optimization by treatment, and/or adding or substituting metal content. The presence and order of these steps may vary. Similarly, methods by which n-type or electron acceptor materials are created from asphaltene material include extraction, fractionation, optimization by treatment, and/or adding or substituting metal content. Again, the presence and order of the steps may vary.

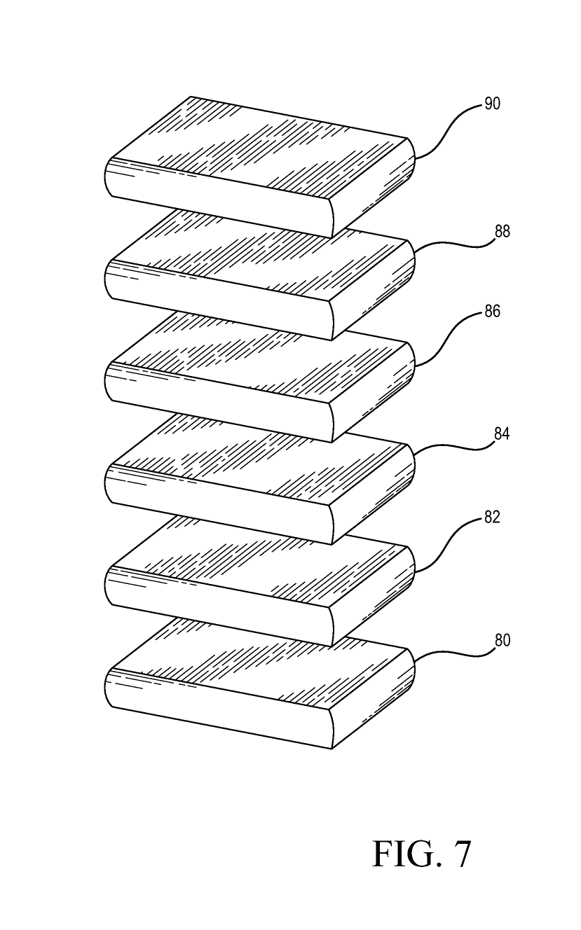

FIG. 6 presents a sample flow-chart of steps for modification of asphaltene material for use in PV cells. For p-type asphaltene material production, an original asphaltene material 60 (such as a refinery left-over or a synthetic asphaltene) undergoes steps such as adding or substitution of metals 62, extraction 64, fractionation 66, and optimization 68 to produce the end-result, p-type asphaltene material 70 for use in a PV cell(s). As explained elsewhere herein, each of the steps is optional. For example, it may not be desirable to add metals to the asphaltene material 60. Similarly, a desired p-type asphaltene 70 may be produced without further optimization 68. Further, the order of steps may be altered and steps can be repeated as desired. FIG. 6 also presents a flow-chart of steps for production of an n-type asphaltene material 72, which includes the step of de-metalization 74. The de-metalization step 74 can occur between any of the other steps, however, it is preferably done prior to extraction, fractionation and optimization. As with the p-type, the n-type production can include some or all of the steps, in various order, and can repeat steps as desired. For example, an asphaltene material may require multiple fractionation steps to achieve a desired fractionation level. Asphaltene modification to p- or n-typing may include any or none of the steps presented above. Other modification schemes and procedures are possible, and are not limited to those presented here.

A p-type asphaltene material can be used in the active layer of a PV cell. For example, the p-type asphaltene material can be blended with an electron acceptor material, such as a fullerene or ZnO, using slow drying and/or thermal annealing processes to create a photo-active layer. The p-type asphaltene material can be used in conjunction with any n-type material, whether organic or inorganic. In a preferred embodiment, the p-type asphaltene material is used in conjunction with an n-type asphaltene material to create an active layer.

An n-type asphaltene material can be used in the photo-active layer of a PV cell. For example, an n-type asphaltene material can be blended with an electron donor material. Preferably, the n-type asphaltene material is used in conjunction with a p-type asphaltene material. Alternately, the n-type asphaltene material can be combined with organic electron donors, such as P3HT, and inorganic electron donors, such as CdTe.

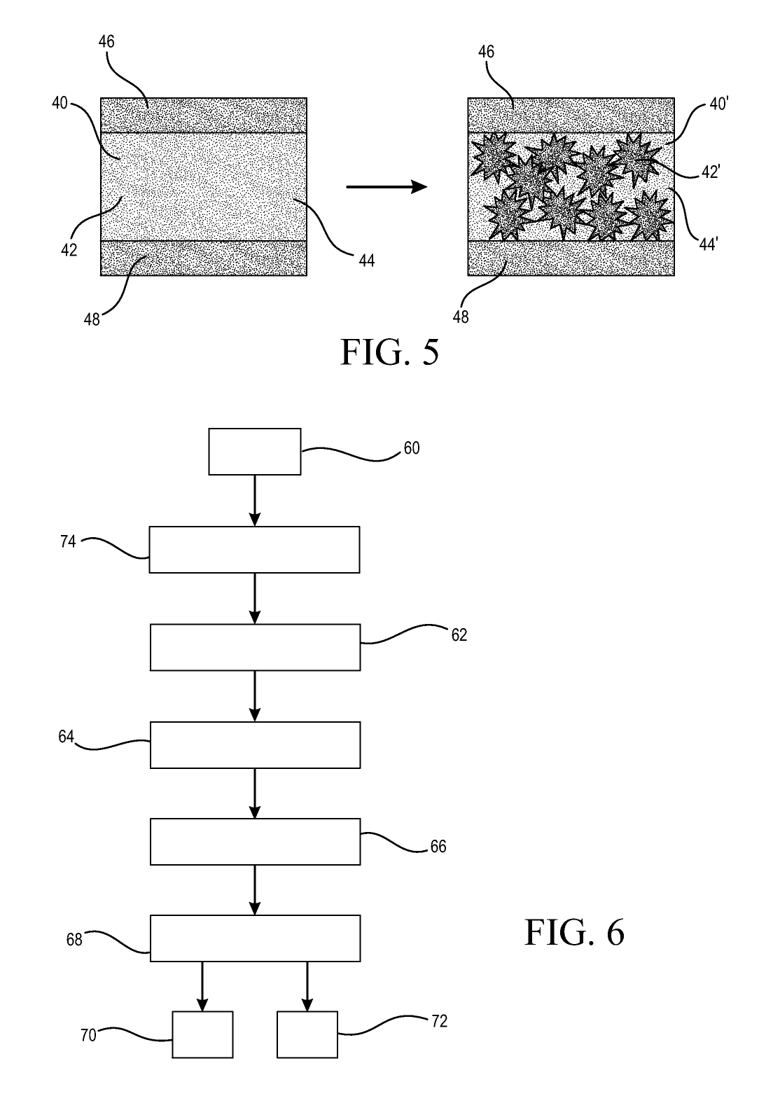

The blending, other combination, and/or treatment of the active layer with donor and acceptor materials can be done after placement of the active layer materials into a partial or complete PV cell. In FIG. 5, the photo-active layer 40, including a p-type asphaltene material 42 and an n-type material 44 (shown as PCBM). The active layer is sandwiched between anode layer 46 and cathode layer 48. The assembled unit is slow dried, thermally annealed, or otherwise treated in accordance with methods known in the art, alone or in combination. The resulting active layer 40′ has p-type asphaltene material 42′ crystallized for maximization of surface area, and the n-type material 44′. This is only an example of such manufacturing. As explained elsewhere herein, the structure and composition of the p- and n-type materials may vary. For example, the p-type material can be an organic non-asphaltene material, an inorganic material, or an asphaltene material. Similarly, the n-type material can be organic non-asphaltene material, inorganic material or asphaltene material. Regardless of the choice of materials, an asphaltene-based material is used as a portion of either the p-type or n-type, or both, materials.

Hybrid PV cells can utilize asphaltene materials. For example, an asphaltene material, whether p-type or n-type, can be used in conjunction with an inorganic photo-active layer material of the opposite type. Further, an electron donor or acceptor material can be created using both an asphaltene material and non-asphaltene material.

FIG. 7 shows an exploded representational view of a sample PV cell having a Transparent Conducting Electrode 80, an Electron Blocking Layer 82, a p-type thin film active layer 84, an n-type organic active layer 86, a Hole Blocking Layer 88 and a low work function layer as an electrode 90. As shown, the n-type organic layer is an asphaltene material while the p-type layer is inorganic. In further embodiments, the p-type layer is asphaltene material while the n-type layer is inorganic.

The asphaltenes described herein can be used to assemble and construct asphaltene-based organic and/or hybrid solar cells, such as BHJ solar cells, DSSC, planar organic semiconductor cells, and hybrid cells.

The PV manufacturing can use solutions processing, such as inkjet printing, spin coating, spray coating, roll-to-roll printing, screen printing, etc. The ease of manufacturing processes using the asphaltene-based active layer is one of the advantages of the invention.

Further, the asphaltene-based PV cells are relatively inexpensive, with the cost of materials and processing orders of magnitude less than production and use of a conventional polymer:fullerene complex.

Finally, asphaltene-based solar cells can easily be built into construction materials like roofing shingles and portable shade structures, or into portable electronics, smart fabrics, etc., to form a durable and robust PV device. Further, the asphaltene-based solar cell can be flexible, such as for use in smart fabrics.

Such asphaltene-based PV cells can be used for utility-scale solar facilities, building-integrated photovoltaics, smart fabrics, portable electronics, and low-cost third-world power generation.

For further disclosure regarding asphaltenes, processing of asphaltenes and photovoltaic devices, see the following, which are hereby incorporated herein in their entirety for all purposes: U.S. patent application Ser. No. 11/561,448 filed Nov. 20, 2006; U.S. patent application Ser. No. 12/933,280 filed Sep. 17, 2010; U.S. patent application Ser. No. 12/935,330 filed Sep. 29, 2010; U.S. patent application Ser. No. 12/190,615 filed Aug. 13, 2008; U.S. patent application Ser. No. 12/614,722 filed Nov. 9, 2009; U.S. patent application Ser. No. 12/833,488 filed Jul. 9, 2010, Chianelli; U.S. patent application Ser. No. 12/191,407 filed Aug. 14, 2008, Irwin; and U.S. Pat. No. 7,407,831 to Brabec et al., issued Aug. 5, 2008.

While the preceding description contains many specifics, it is to be understood that same are presented only to describe some of the presently preferred embodiments of the invention, and not by way of limitation. Changes can be made to various aspects of the invention, without departing from the scope thereof. Therefore, the scope of the invention is not to be limited to the illustrative examples set forth above, but encompasses modifications which may become apparent to those of ordinary skill in the relevant art.

It is claimed:

1. An organic photovoltaic device comprising:
a first electrically conductive layer;
an active layer having both p-type and n-type material, wherein one of the p-type or n-type material is an asphaltene material; and
a second electrically conductive layer, the first and second electrically conductive layers on opposing sides of the active layer.

2. A device as in claim 1, wherein the device is a dye-sensitized solar cell, a planar organic solar cell, a hybrid solar cell, or a bulk-heterojunction solar cell.

3. A device as in claim 1, wherein the asphaltene material is de-metalized.

4. A device as in claim 1, wherein at least a portion of the asphaltene material is an extractate.

5. A device as in claim 4, wherein the extractate is selected from the group comprising: Pentane Asphaltenes, Hexane Asphaltenes, Heptane Asphaltenes, Octane Asphaltenes, Nonane Asphaltenes and alkane asphaltenes.

6. A device as in claim 1, wherein the asphaltene material is synthetic.

7. A device as in claim 1, wherein the asphaltene material includes at least one metal artificially added to the asphaltene material.

8. A device as in claim 1, wherein the asphaltene material is fractionated and contains a selected percentage constituency of selected elements.

9. A device as in claim 1, wherein the asphaltene material is treated to optimize at least a characteristic of the asphaltene material, the characteristic being absorption value, reflectance, index of refraction, band gap, molecular orbital energy value, effective wavelength utility, charge carrier concentration, charge carrier mobility, charge carrier effective mass, or conductivity.

10. A device as in claim 1, wherein the active layer further includes an inorganic n-type or p-type material.

11. A device as in claim 1, wherein both the p-type and n-type material are asphaltene materials.

12. A method of treating asphaltene material for use in a photovoltaic device, the method comprising the following steps:
creating an asphaltene-based p-type material or an asphaltene-based n-type material from an asphaltene material; and
using the asphaltene-based p-type material or n-type material in a photovoltaic device.

13. A method as in claim 12, wherein the step of creating an asphaltene-based p-type material or an asphaltene-based n-type material from an asphaltene material further comprises at least one of the following treatment steps: de-metalization, metal addition, extraction, fractionation, and optimization of the asphaltene material.

14. A method as in claim 13, wherein the treatment steps are selected to create an asphaltene-based material having a pre-selected characteristic, the characteristic being absorption value, reflectance, index of refraction, band gap, molecular orbital energy value, effective wavelength utility, charge carrier concentration, charge carrier mobility, charge carrier effective mass, or conductivity.

15. A method as in claim 12, wherein the photovoltaic device is a dye-sensitized solar cell, a planar organic semiconductor cell, a hybrid solar cell, or a BHJ cell.

16. A method as in claim 12, further comprising the step of blending an inorganic semiconductor material with the asphaltene-based p-type or n-type material.

17. A method as in claim 12, wherein the step of using the asphaltene-based material further comprises the step of positioning the asphaltene-based material between electrode layers.

18. A method as in claim 17, further comprising the step of positioning the asphaltene-based material adjacent at least one interfacial layer.

19. A method as in claim 18, wherein the at least one interfacial layer is an asphaltene-based material.

20. A method as in claim 12, wherein the step of creating an asphaltene-based p-type material or an asphaltene-based n-type material from an asphaltene material, further includes the step of creating a fully-synthetic asphaltene material.

21. A method as in claim 12, wherein the step of creating an asphaltene-based p-type material or an asphaltene-based n-type material from an asphaltene material includes the step of extracting a Pentane Asphaltene, Hexane Asphaltene, Heptane Asphaltene, Octane Asphaltene, Nonane Asphaltene or other alkane asphaltene.

22. A method as in claim 13, further comprising the step of repeating at least one of the treatment steps.

23. A method as in claim 12, further comprising the step of blending the asphaltene-based p-type material or an asphaltene-based n-type material from an asphaltene material with an inorganic material or a non-asphaltene organic material.
